(19) United States
(12) Patent Application Publication
(10) Pub. No.: US 2025/0151594 A1
(43) Pub. Date: May 8, 2025

(54) DISPLAY DEVICE

(71) Applicant: Samsung Display Co., LTD., Yongin-si (KR)

(72) Inventors: HONGAM KIM, Yongin-si (KR); SEUNGSUE RYU, Yongin-si (KR); KIKYUNG YOUK, Yongin-si (KR)

(21) Appl. No.: 18/749,443

(22) Filed: Jun. 20, 2024

(30) Foreign Application Priority Data
Nov. 6, 2023 (KR) 10-2023-0152212

(51) Int. Cl. H01L 33/62; H01L 25/075; H01L 25/16

(52) U.S. Cl. CPC H10K 59/95; H01L 25/167; H10H 20/857

(57) ABSTRACT

A display device includes a substrate including a display area, and a pad area at one side of the display area, a pad electrode above the substrate in the pad area, and including a first conductive pattern, a driving chip above the substrate in the pad area, and overlapping the pad electrode in plan view, an insulating layer above the substrate, and defining an opening exposing a portion of the first conductive pattern, and an adhesive member connecting the pad electrode and the driving chip, and including conductive balls repeatedly arranged along a first direction, wherein the opening includes first openings spaced apart from each other in the first direction, and having a first width in a second direction crossing the first direction that is substantially equal to a diameter of the conductive balls, and second openings respectively connecting adjacent ones of the first openings.

### CROSS-REFERENCE TO RELATED APPLICATION

The present application claims priority to, and the benefit of, Korean Patent Application No. 10-2023-0152212, filed on Nov. 6, 2023, in the Korean Intellectual Property Office, the entire disclosure of which is incorporated herein by reference.

### BACKGROUND

### 1. Field

The present disclosure relates to a display device that provides visual information.

### 2. Description of the Related Art

With the development of information technology, the importance of a display device, which is a connection medium between a user and information, has been highlighted. For example, there is increasing use of display devices, such as liquid crystal display (LCD) device, organic light-emitting display (OLED) device, plasma display panel (PDP) device, quantum dot display device, or the like.

A display device may include pixels for generating an image, and may include a pad electrode and a driving chip that provide signals to the pixels. The pad electrode may be electrically connected to the driving chip by an adhesive member (e.g., an anisotropic conductive film). That is, the pad electrode may be electrically connected to the driving chip by a conductive ball included in the adhesive member.

### SUMMARY

Embodiments provide a display device with an improved connection between a pad electrode and a driving chip.

A display device according to one or more embodiments of the present disclosure includes a substrate including a display area, and a pad area at one side of the display area, a pad electrode above the substrate in the pad area, and including a first conductive pattern, a driving chip above the substrate in the pad area, and overlapping the pad electrode in plan view, an insulating layer above the substrate, and defining an opening exposing a portion of the first conductive pattern, and an adhesive member connecting the pad electrode and the driving chip, and including conductive balls repeatedly arranged along a first direction, wherein the opening includes first openings spaced apart from each other in the first direction, and having a first width in a second direction crossing the first direction that is substantially equal to a diameter of the conductive balls, and second openings respectively connecting adjacent ones of the first openings.

A distance in the first direction between centers of adjacent ones of the conductive balls in the first direction may be substantially equal to a first length of the first openings in the first direction.

A first length of the first openings in the first direction may be greater than a second width of the second openings in the first direction.

The first width may be less than a second length of the second openings in the second direction.

A first length of the first openings in the first direction may be greater than the first width, wherein a second width of the second openings in the first direction is less than a second length of the second openings in the second direction.

The second openings may be alternately arranged with the first openings in plan view.

The first openings and the second openings may be aligned along the first direction.

The display device may further include an active pattern above the substrate in the display area, a gate electrode above the active pattern, and a source electrode and a drain electrode at a layer above the gate electrode, wherein the first conductive pattern is at a same layer as the gate electrode.

The display device may further include a connection electrode above the drain electrode in the display area, and a sensing electrode above the connection electrode.

The pad electrode further may include a second conductive pattern above the first conductive pattern, and at a same layer as the source electrode and the drain electrode, a third conductive pattern above the second conductive pattern, and at a same layer as the connection electrode, and a fourth conductive pattern above the third conductive pattern, and at a same layer as the sensing electrode.

The second conductive pattern may be located along profiles of the first conductive pattern and the insulating layer.

The third conductive pattern may cover the second conductive pattern, and is located along profiles of the second conductive pattern and the insulating layer.

The fourth conductive pattern may be located along a profile of the third conductive pattern and overlapping the opening in plan view.

A display device according to one or more other embodiments of the present disclosure includes a substrate including a display area, and a pad area at one side of the display area, a pad electrode above the substrate in the pad area, and including a first conductive pattern, a driving chip above the substrate in the pad area, and overlapping the pad electrode in plan view, an insulating layer above the substrate, and defining an opening exposing a portion of the first conductive pattern, and an adhesive member connecting the pad electrode and the driving chip, and including conductive balls repeatedly arranged along a first direction, wherein the opening includes first openings spaced apart from each other in the first direction, having a first length in the first direction substantially equal to a distance between centers of adjacent ones of the conductive balls in the first direction, and second openings respectively connecting adjacent ones of the first openings.

The first length may be greater than a second width of the second openings in the first direction.

A first width of the first openings in a second direction crossing the first direction may be less than a second length of the second openings in the second direction.

The first length may be greater than a first width of the first openings in a second direction crossing the first direction, wherein a second width of the second openings in the first direction is less than a second length of the second openings in the second direction.

The first openings and the second openings may be aligned along the first direction.

The display device may further include an active pattern above the substrate in the display area, a gate electrode above the active pattern, a source electrode and a drain electrode at a layer above the gate electrode, a connection electrode above the drain electrode, and a sensing electrode above the connection electrode, wherein the first conductive pattern is at a same layer as the gate electrode.

The pad electrode may further include a second conductive pattern above the first conductive pattern at a same layer as the source electrode and the drain electrode, a third conductive pattern above the second conductive pattern at a same layer as the connection electrode, and a fourth conductive pattern above the third conductive pattern at a same layer as the sensing electrode.

A display device according to one or more embodiments of the present disclosure may include a pad electrode including a first conductive pattern, a driving chip overlapping the pad electrode in a plan view, an insulating layer defining an opening exposing at least a portion of the first conductive pattern, and an adhesive member connecting the pad electrode and the driving chip, and including a plurality of conductive balls repeatedly arranged along a first direction. The opening may include first openings spaced apart from each other in the first direction, and the first openings may have a shape that accounts for a diameter of each of the conductive balls and a planar arrangement of the conductive balls.

Accordingly, the frequency with which the conductive balls are captured by the pad electrode may increase. In other words, the frequency with which the conductive balls directly contact the pad electrode may increase. As a result, a defect in which the pad electrode and the driving chip are not electrically connected may be suppressed.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is a cross-sectional view taken along the line I-I′ of FIG. 1.

FIGS. 3 and 4 are cross-sectional views taken along the line II-II′ of FIG. 1.

FIG. 5 is a plan view illustrating an adhesive member included in the display device of FIG. 1.

FIG. 6 is an enlarged plan view of area ‘A’ of FIG. 1.

FIG. 7 is a cross-sectional view taken along the line III-III′ of FIG. 6.

FIG. 8 is a cross-sectional view taken along the line IV-IV′ of FIG. 6.

FIG. 9 is a plan view illustrating a pad area of a display device according to a comparative example.

FIG. 10 is a cross-sectional view taken along the line V-V′ of FIG. 9.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

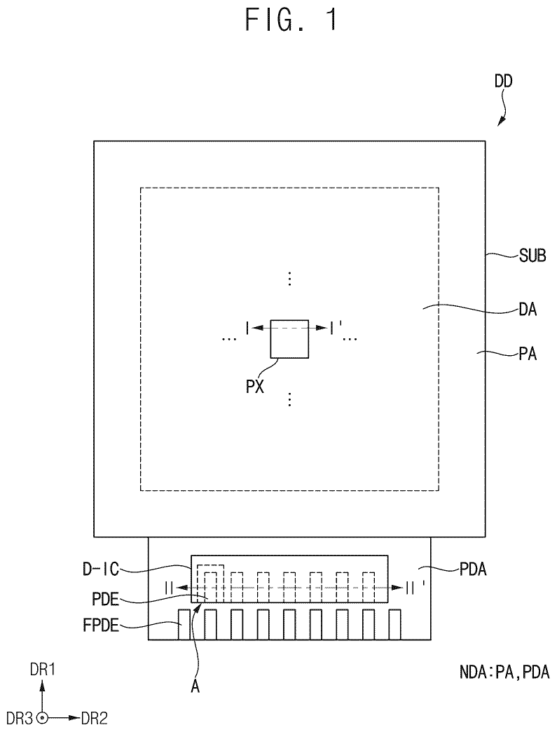

FIG. 1 is a plan view illustrating a display device according to one or more embodiments of the present disclosure.

In this specification, a plane may be defined by a first direction DR1 and by a second direction DR2 intersecting the first direction DR1. For example, the first direction DR1 and the second direction DR2 may be substantially perpendicular to each other. A direction normal to the plane, that is, a thickness direction of a display device DD may be a third direction DR3. In other words, the third direction DR3 may be substantially perpendicular to each of the first direction DR1 and the second direction DR2.

Referring to FIG. 1, the display device DD according to one or more embodiments of the present disclosure may include a substrate SUB, a driving chip D-IC, a plurality of pad electrodes PDE, and a plurality of circuit board pad electrodes FPDE.

The substrate SUB may include a display area DA and a non-display area NDA. The display area DA may be defined as an area where an image may be displayed. A plurality of pixels PX for generating an image may be located in the display area DA. The image may be generated by combining light emitted from each of the pixels PX. For example, the pixels PX may be located in a matrix form along the first direction DR1 and the second direction DR2.

The non-display area NDA may be defined as an area that does not display an image. The non-display area NDA may include a peripheral area PA and a pad area PDA. The peripheral area PA may be positioned around the display area DA. For example, the peripheral area PA may surround the display area DA in a plan view.

The pad area PDA may be positioned on one side of the display area DA. For example, the pad area PDA may be spaced apart from the display area DA in the first direction DR1. The pad area PDA may extend in the second direction DR2. The plurality of pad electrodes PDE and the plurality of circuit board pad electrodes FPDE may be located in the pad area PDA.

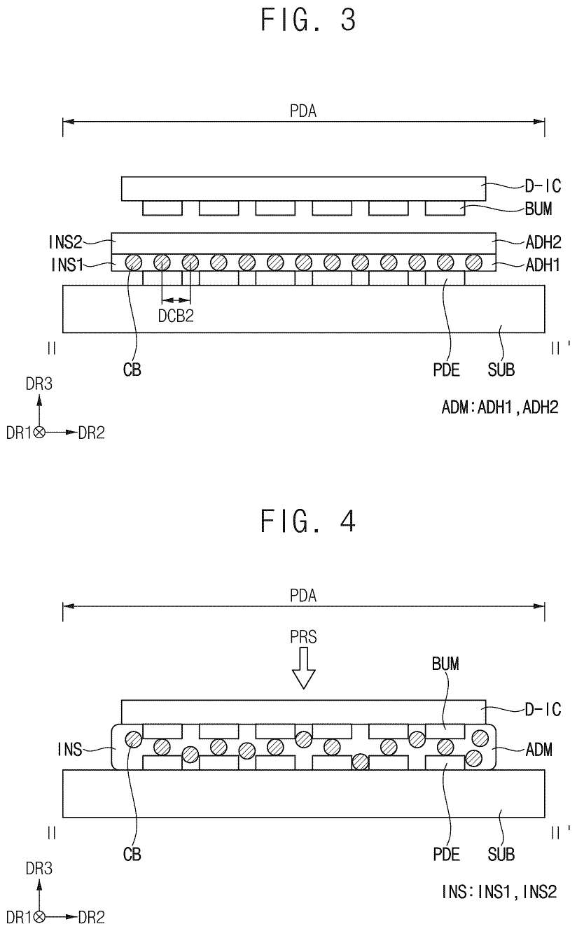

The driving chip D-IC may be located on the substrate SUB in the pad area PDA. The driving chip D-IC may overlap the pad electrodes PDE in a plan view. The driving chip D-IC may be connected to the pad electrodes PDE through an adhesive member (e.g., an adhesive member ADM of FIG. 3). For example, the driving chip D-IC may include a plurality of bumps (e.g., bumps BUM of FIG. 3), and the plurality of bumps may be connected to the pad electrodes PDE through the adhesive member. A detailed description thereof will be described below with reference to FIGS. 3 and 4.

The driving chip D-IC may provide a driving signal to the pixels PX. The driving signal may refer to various signals that drive the pixels PX, such as a driving voltage, control signal, data signal, etc.

In one or more embodiments, the circuit board may be located on the substrate SUB in the pad area PDA. The circuit board may overlap the circuit board pad electrodes FPDE in a plan view. The circuit board may be connected to the circuit board pad electrodes FPDE through the adhesive member. For example, the circuit board may be a flexible printed circuit board.

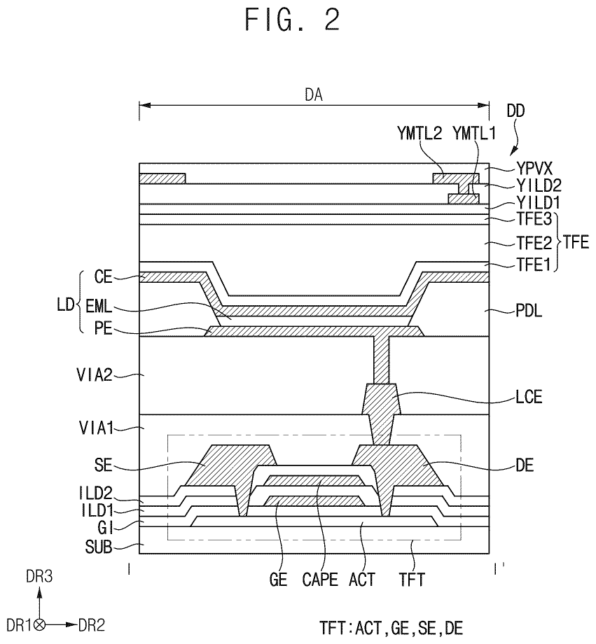

FIG. 2 is a cross-sectional view taken along the line I-I′ of FIG. 1.

Referring to FIG. 2, in the display area DA, the display device DD according to one or more embodiments of the present disclosure may include the substrate SUB, a gate-insulating layer GI, a first inter-layer insulating layer ILD1, a second inter-layer insulating layer ILD2, a thin film transistor TFT, a capacitor electrode CAPE, a first via-insulating layer VIA1, a connection electrode LCE, a second via-insulating layer VIA2, a pixel-defining layer PDL, a light-emitting element LD, an encapsulation layer TFE, a first touch insulating layer YILD1, a first sensing electrode YMTL1, a second touch insulating layer YILD2, a second sensing electrode YMTL2, and a touch protection layer YPVX.

The thin film transistor TFT may include an active pattern ACT, a gate electrode GE, a source electrode SE, and a drain electrode DE. The light-emitting element LD may include a pixel electrode PE, a light-emitting layer EML, and a common electrode CE. The encapsulation layer TFE may include a first inorganic encapsulation layer TFE1, an organic encapsulation layer TFE2, and a second inorganic encapsulation layer TFE3.

The substrate SUB may include a transparent material or an opaque material. For example, the substrate SUB may be formed of a transparent resin substrate. A polyimide substrate may be an example of the transparent resin substrate. In this case, the polyimide substrate may include a first organic layer, a first barrier layer, a second organic layer, etc. Alternatively, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

A buffer layer may be located on the substrate SUB. The buffer layer may reduce or prevent diffusion of metal atoms or impurities from the substrate SUB to an upper structure (e.g., the thin film transistor TFT, the light-emitting element LD, etc.). In addition, the buffer layer may obtain the substantially uniform active pattern ACT by controlling a heat transfer rate during a crystallization process for forming the active pattern ACT. In addition, the buffer layer may serve to improve flatness of a surface of the substrate SUB when the surface of the substrate SUB is not uniform. For example, the buffer layer may include an inorganic insulating material. Alternatively, the buffer layer may be omitted.

The active pattern ACT may be located on the substrate SUB. The active pattern ACT may include an oxide semiconductor, a silicon semiconductor, an organic semiconductor, etc. For example, the oxide semiconductor may include at least one oxide selected from indium (In), gallium (Ga), tin (Sn), zirconium (Zr), vanadium (V), hafnium (Hf), cadmium (Cd), germanium (Ge), chromium (Cr), titanium (Ti), or zinc (Zn). The silicon semiconductor may include amorphous silicon, polycrystalline silicon, etc. The active pattern ACT may include a source area, a drain area, and a channel area positioned between the source area and the drain area.

The gate-insulating layer GI may be located on the substrate SUB. The gate-insulating layer GI may cover the active pattern ACT on the substrate SUB, and may be located along the profile of the active pattern ACT with a substantially uniform thickness. Alternatively, the gate-insulating layer GI may sufficiently cover the active pattern ACT on the substrate SUB, and may have a substantially flat upper surface without creating a step difference around the active pattern ACT. The gate-insulating layer GI may include an inorganic insulating material. Examples of the inorganic insulating material that may be used as the gate-insulating layer GI may include silicon oxide (SiOₓ), silicon nitride (SiNₓ), silicon oxynitride (SiOₓN_{y}), etc. These may be used alone or in combination with each other. The gate-insulating layer GI may electrically insulate the active pattern ACT and the gate electrode GE.

The gate electrode GE may be located on the gate-insulating layer GI. The gate electrode GE may overlap the channel area of the active pattern ACT in a plan view. The gate electrode GE may include a metal, an alloy, a metal nitride, a conductive metal oxide, a transparent conductive material, etc. Examples of material that may be used as the gate electrode GE may include silver (Ag), an alloy including silver, molybdenum (Mo), an alloy including molybdenum, aluminum (AI), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other.

The first inter-layer insulating layer ILD1 may be located on the gate-insulating layer GI. The first inter-layer insulating layer ILD1 may cover the gate electrode GE on the gate-insulating layer GI, and may be located along the profile of the gate electrode GE with a substantially uniform thickness. Alternatively, the first inter-layer insulating layer ILD1 may sufficiently cover the gate electrode GE on the gate-insulating layer GI, and may have a substantially flat upper surface without creating a step difference around the gate electrode GE. The first inter-layer insulating layer ILD1 may include an inorganic insulating material. Examples of the inorganic insulating material that may be used as the first inter-layer insulating layer ILD1 may include silicon oxide (SiOₓ), silicon nitride (SiNₓ), silicon oxynitride (SiOₓN_{y}), etc. These may be used alone or in combination with each other. The first inter-layer insulating layer ILD1 may electrically insulate the gate electrode GE and the source electrode SE. In addition, the first inter-layer insulating layer ILD1 may electrically insulate the gate electrode GE and the drain electrode DE. In addition, the first inter-layer insulating layer ILD1 may electrically insulate the gate electrode GE and the capacitor electrode CAPE.

The capacitor electrode CAPE may be located on the first inter-layer insulating layer ILD1. The capacitor electrode CAPE may overlap the gate electrode GE in a plan view. The capacitor electrode CAPE may form a capacitor (e.g., a storage capacitor) together with the gate electrode GE. For example, the capacitor electrode CAPE may include a metal, an alloy, a metal nitride, a conductive metal oxide, a transparent conductive material, etc. These may be used alone or in combination with each other.

The second inter-layer insulating layer ILD2 may be located on the first inter-layer insulating layer ILD1. The second inter-layer insulating layer ILD2 may cover the capacitor electrode CAPE on the first inter-layer insulating layer ILD1, and may be located along the profile of the capacitor electrode CAPE with a substantially uniform thickness. Alternatively, the second inter-layer insulating layer ILD2 may sufficiently cover the capacitor electrode CAPE on the first inter-layer insulating layer ILD1, and may have a substantially flat upper surface without creating a step difference around the capacitor electrode CAPE. The second inter-layer insulating layer ILD2 may include an inorganic insulating material. Examples of the inorganic insulating material that may be used as the second inter-layer insulating layer ILD2 may include silicon oxide (SiOₓ), silicon nitride (SiNₓ), silicon oxynitride (SiOₓN_{y}), etc. These may be used alone or in combination with each other. The second inter-layer insulating layer ILD2 may electrically insulate the capacitor electrode CAPE and the source electrode SE. In addition, the second inter-layer insulating layer ILD2 may electrically insulate the capacitor electrode CAPE and the drain electrode DE.

The source electrode SE and the drain electrode DE may be located on the second inter-layer insulating layer ILD2. The source electrode SE may be connected to the source area of the active pattern ACT through a contact hole formed by removing a first portion of the gate-insulating layer GI, the first inter-layer insulating layer ILD1, and the second inter-layer insulating layer ILD2. The drain electrode DE may be connected to the drain area of the active pattern ACT through a contact hole formed by removing a second portion of the gate-insulating layer GI, the first inter-layer insulating layer ILD1, and the second inter-layer insulating layer ILD2. For example, each of the source electrode SE and the drain electrode DE may include a metal, an alloy, a metal nitride, a conductive metal oxide, a transparent conductive material, etc. These may be used alone or in combination with each other.

The first via-insulating layer VIA1 may be located on the second inter-layer insulating layer ILD2. For example, the first via-insulating layer VIA1 may be located on the second inter-layer insulating layer ILD2 with a relatively thick thickness to sufficiently cover the source electrode SE and the drain electrode DE. In this case, the first via-insulating layer VIA1 may have a substantially flat upper surface, and a process for flattening the first via-insulating layer VIA1 may be added to implement the flat upper surface of the first via-insulating layer VIA1. The first via-insulating layer VIA1 may include an organic insulating material. Examples of the organic insulating material that may be used as the first via-insulating layer VIA1 may include photoresist, polyacryl-based resin, polyimide-based resin, polyamide-based resin, siloxane-based resin, acryl-based resin, epoxy-based resin, etc. These may be used alone or in combination with each other.

The connection electrode LCE may be located on the first via-insulating layer VIA1. The connection electrode LCE may be connected to the drain electrode DE through a contact hole formed by removing a portion of the first via-insulating layer VIA1. For example, the connection electrode LCE may include a metal, an alloy, a metal nitride, a conductive metal oxide, a transparent conductive material, etc. These may be used alone or in combination with each other.

The second via-insulating layer VIA2 may be located on the first via-insulating layer VIA1. For example, the second via-insulating layer VIA2 may be located on the first via-insulating layer VIA1 with a relatively thick thickness to sufficiently cover the connection electrode LCE. In this case, the second via-insulating layer VIA2 may have a substantially flat upper surface, and a process for flattening the second via-insulating layer VIA2 may be added to implement the flat upper surface of the second via-insulating layer VIA2. The second via-insulating layer VIA2 may include an organic insulating material. Examples of the organic insulating material that may be used as the second via-insulating layer VIA2 may include photoresist, polyacryl-based resin, polyimide-based resin, polyamide-based resin, siloxane-based resin, acryl-based resin, epoxy-based resin, etc. These may be used alone or in combination with each other.

The pixel electrode PE may be located on the second via-insulating layer VIA2. The pixel electrode PE may be connected to the connection electrode LCE through a contact hole formed by removing a portion of the second via-insulating layer VIA2. Accordingly, the pixel electrode PE may be electrically connected to the thin film transistor TFT through the connection electrode LCE. For example, the pixel electrode PE may include a metal, an alloy, a metal nitride, a conductive metal oxide, a transparent conductive material, etc. These may be used alone or in combination with each other. For example, the pixel electrode PE may serve as an anode electrode.

The pixel-defining layer PDL may be located on the second via-insulating layer VIA2. The pixel-defining layer PDL may cover an edge of the pixel electrode PE, and may have/define an opening that exposes an upper surface of the pixel electrode PE. For example, the pixel-defining layer PDL may include an organic insulating material or an inorganic insulating material. In one or more embodiments, the pixel-defining layer PDL may include an organic insulating material. Examples of the organic insulating material that may be used as the pixel-defining layer PDL may include photoresist, polyacryl-based resin, polyimide-based resin, polyamide-based resin, siloxane-based resin, acryl-based resin, epoxy-based resin, etc. These may be used alone or in combination with each other.

The light-emitting layer EML may be located on the pixel electrode PE. The light-emitting layer EML may be located on the upper surface of the pixel electrode PE exposed by the pixel-defining layer PDL. The light-emitting layer EML may emit light having corresponding colors (e.g., red, green, and blue). In one or more embodiments, the light-emitting layer EML may include one or both of an organic light-emitting material and a quantum dot. For example, the light-emitting layer EML may include an organic light-emitting material including a fluorescent or phosphorescent material that emits red, green, blue, or white light. The quantum dot may be a particle having a crystal structure of several to tens of nanometers in size, and may include hundreds to thousands of atoms. The quantum dot may include a fluorescent material or a phosphorescent material, and may produce monochromatic red, green, and blue light.

The common electrode CE may be located on the pixel-defining layer PDL and the light-emitting layer EML. The common electrode CE may be located with a uniform thickness along the profiles of the pixel-defining layer PDL and the light-emitting layer EML. For example, the common electrode CE may include a metal, an alloy, a metal nitride, a conductive metal oxide, a transparent conductive material, etc. These may be used alone or in combination with each other. For example, the common electrode CE may serve as a cathode electrode.

The encapsulation layer TFE may be located on the common electrode CE. The encapsulation layer TFE may reduce or prevent impurities, moisture, etc. penetrating into the light-emitting element LD from the outside. The encapsulation layer TFE may include at least one inorganic encapsulation layer and at least one organic encapsulation layer. In one or more embodiments, the encapsulation layer TFE may include the first inorganic encapsulation layer TFE1, the organic encapsulation layer TFE2, and the second inorganic encapsulation layer TFE3.

The first inorganic encapsulation layer TFE1 may be located on the common electrode CE. The first inorganic encapsulation layer TFE1 may cover the common electrode CE and may be located along the profile of the common electrode CE with a uniform thickness. The first inorganic encapsulation layer TFE1 may reduce or prevent deterioration of the light-emitting element LD due to penetration of impurities, moisture, etc. In addition, the first inorganic encapsulation layer TFE1 may protect the light-emitting element LD from external impact. For example, the first inorganic encapsulation layer TFE1 may include a flexible inorganic insulating material.

The organic encapsulation layer TFE2 may be located on the first inorganic encapsulation layer TFE1. The organic encapsulation layer TFE2 may compensate for a step difference of the first inorganic encapsulation layer TFE1. Accordingly, the organic encapsulation layer TFE2 may have a substantially flat upper surface. The organic encapsulation layer TFE2 may protect the light-emitting element LD from external impact together with the first inorganic encapsulation layer TFE1. For example, the organic encapsulation layer TFE2 may include a flexible organic material.

The second inorganic encapsulation layer TFE3 may be located on the organic encapsulation layer TFE2. The second inorganic encapsulation layer TFE3 may reduce or prevent deterioration of the light-emitting element LD due to penetration of impurities, moisture, etc. together with the first inorganic encapsulation layer TFE1. In addition, the second inorganic encapsulation layer TFE3 may protect the light-emitting element LD from external impact together with the first inorganic encapsulation layer TFE1 and the organic encapsulation layer TFE2. For example, the second inorganic encapsulation layer TFE3 may include a flexible inorganic insulating material.

In one or more other embodiments, the encapsulation layer TFE may have a five-layer structure with three inorganic encapsulation layers and two organic encapsulation layers alternatively stacked with each other, or the encapsulation layer TFE may have a seven-layer structure with four inorganic encapsulation layers and three organic encapsulation layers alternatively stacked with each other.

The first touch insulating layer YILD1 may be located on the second inorganic encapsulation layer TFE3. For example, the first touch insulating layer YILD1 may include an inorganic insulating material or an organic insulating material.

The first sensing electrode YMTL1 may be located on the first touch insulating layer YILD1. The first sensing electrode YMTL1 may include a metal, an alloy, a metal nitride, a conductive metal oxide, a transparent conductive material, etc. These may be used alone or in combination with each other.

The second touch insulating layer YILD2 may be located on the first touch insulating layer YILD1. The second touch insulating layer YILD2 may cover the first sensing electrode YMTL1. For example, the second touch insulating layer YILD2 may include an inorganic insulating material or an organic insulating material.

The second sensing electrode YMTL2 may be located on the second touch insulating layer YILD2. The second sensing electrode YMTL2 may be connected to the first sensing electrode YMTL1 through a contact hole formed by removing a portion of the first touch insulating layer YILD1. For example, the second sensing electrode YMTL2 may include a metal, an alloy, a metal nitride, a conductive metal oxide, a transparent conductive material, etc. These may be used alone or in combination with each other.

The touch protection layer YPVX may be located on the second touch insulating layer YILD2. The touch protection layer YPVX may cover the second sensing electrode YMTL2. For example, the touch protection layer YPVX may include an inorganic insulating material or an organic insulating material.

Although the display device DD of the present disclosure is described by limiting the organic light-emitting display (OLED) device, the configuration of the present disclosure is not limited thereto. In other embodiments, the display device DD may include a liquid crystal display (LCD) device, a field emission display (FED) device, a plasma display panel (PDP) device, an electrophoretic image display (EPD) device, an inorganic light-emitting display (ILED) device, or a quantum dot display device.

FIGS. 3 and 4 are cross-sectional views taken along the line II-II′ of FIG. 1. For example, FIG. 3 is a cross-sectional view illustrating a state before the pad electrodes PDE and the driving chip D-IC are bonded. FIG. 4 is a cross-sectional view illustrating a state in which the pad electrodes PDE and the driving chip D-IC are bonded.

Referring to FIG. 3, in the pad area PDA, the display device DD according to one or more embodiments of the present disclosure may include the substrate SUB, the pad electrodes PDE, the driving chip D-IC, and an adhesive member ADM.

The pad electrodes PDE may be located on the substrate SUB in the pad area PDA. The pad electrodes PDE may be repeatedly located along the second direction DR2. In addition, in one or more embodiments, the pad electrodes PDE may be repeatedly located along the first direction DR1. The pad electrodes PDE may include a plurality of input pads and a plurality of output pads.

The input pads may receive a driving signal, which is provided by the circuit board, from the circuit board pad electrodes (e.g., the circuit board pad electrodes FPDE of FIG. 1). The output pads may transmit a driving signal, which is provided by the driving chip D-IC, to the pixels (e.g., the pixels PX of FIG. 1).

The driving chip D-IC may be located on the pad electrodes PDE. The driving chip D-IC may overlap the pad electrodes PDE in a plan view. The driving chip D-IC may include a plurality of bumps BUM. The bumps BUM may be repeatedly located along the second direction DR2. In addition, in one or more embodiments, the bumps BUM may be repeatedly located along the first direction DR1. The bumps BUM may include input bumps, output bumps, and alignment bumps.

When the pad electrodes PDE and the driving chip D-IC are bonded by the adhesive member ADM, the input bumps may be connected to the input pads, and the output bumps may be connected to the output pads. The alignment bumps may be used to align the driving chip D-IC and the pad electrodes PDE.

The adhesive member ADM may be located between the pad electrodes PDE and the driving chip D-IC. The adhesive member ADM may extend in the second direction DR2. In addition, in one or more embodiments, the adhesive member ADM may extend in the first direction DR1. The adhesive member ADM may entirely cover the pad electrodes PDE. The adhesive member ADM may include a first adhesive layer ADH1 and a second adhesive layer ADH2 located on the first adhesive layer ADH1.

The first adhesive layer ADH1 may be located on the pad electrodes PDE. The first adhesive layer ADH1 may include a first adhesive material INS1 and a plurality of conductive balls CB.

The first adhesive material INS1 may be an adhesive material having insulating properties. For example, the first adhesive material INS1 may include thermoplastic resin and/or thermosetting resin. Examples of the thermoplastic resin that may be used as the first adhesive material INS1 may include acrylic resin, vinyl resin, polyolefin resin, polycarbonate resin, etc. These may be used alone or in combination with each other. Examples of the thermosetting resin that may be used as the first adhesive material INS1 may include epoxy resin, phenol resin, melamine resin, etc. These may be used alone or in combination with each other.

The conductive balls CB may be located in the first adhesive layer ADH1. The conductive balls CB may be repeatedly arranged along the second direction DR2. In addition, in one or more embodiments, the conductive balls CB may be repeatedly arranged along the first direction DR1. The conductive balls CB may be spaced apart from each other at equal intervals in the second direction DR2. For example, a distance DCB2 in the second direction DR2 between centers of the conductive balls CB adjacent to each other in the second direction DR2 may be about 3.2 micrometers. However, the present disclosure is not limited thereto.

The second adhesive layer ADH2 may be located on the first adhesive layer ADH1. The second adhesive layer ADH2 may include a second adhesive material INS2. The second adhesive layer ADH2 may not include the conductive balls CB. The second adhesive material INS2 may be an adhesive material having insulating properties. For example, the second adhesive material INS2 may include thermoplastic resin and/or thermosetting resin.

In one or more embodiments, the second adhesive material INS2 may include the same material as the first adhesive material INS1. However, the present disclosure is not limited thereto, and the second adhesive material INS2 may include a different material from the first adhesive material INS1. Alternatively, the second adhesive layer ADH2 may be omitted. In this case, the adhesive member ADM may have a single-layer structure.

In one or more embodiments, a first modulus of the first adhesive layer ADH1 may be greater than a second modulus of the second adhesive layer ADH2. As the first adhesive layer ADH1 has the relatively large first modulus, during the process of bonding the pad electrodes PDE and the driving chip D-IC, the first adhesive layer ADH1 may reduce the disruption of the arrangement of the conductive balls CB. As the second adhesive layer ADH2 has the relatively small second modulus, during the process of bonding the pad electrodes PDE and the driving chip D-IC, the second adhesive layer ADH2 may widely spread on the substrate SUB and the pad electrodes PDE, to improve the adhesion of the adhesive member ADM.

Referring further to FIG. 4, the driving chip D-IC may be bonded to the pad electrodes PDE by heat and pressure.

The pressure PRS may be applied to one surface of the driving chip D-IC toward the substrate SUB. In this case, the one surface of the driving chip D-IC may refer to a surface of the driving chip D-IC that is opposite to a surface on which the bumps BUM are located. When the driving chip D-IC applies pressure PRS to the adhesive member ADM, the adhesive member ADM may widely spread on the substrate SUB and the pad electrodes PDE. An adhesive material INS may surround the conductive balls CB. Here, the adhesive material INS may include the first adhesive material INS1 and the second adhesive material INS2.

The conductive balls CB may be located between pad electrodes PDE and the bumps BUM. One side of each of the conductive balls CB may directly contact one pad electrode PDE, and the other side of each of the conductive balls CB may directly contact one bump BUM. Accordingly, the conductive balls CB may electrically connect the pad electrodes PDE and the bumps BUM. In other words, the conductive balls CB may connect the pad electrodes PDE and the driving chip D-IC.

Compared to a case before the pad electrodes PDE and the driving chip D-IC are bonded, as the pad electrodes PDE and the driving chip D-IC are bonded together by the pressure PRS, the arrangement of the conductive balls CB may be deformed. As the arrangement of the conductive balls CB is deformed, some of the conductive balls CB may not contact the pad electrodes PDE and/or the bumps BUM. If a contact defect of the conductive balls CB occurs, a defect in which some of the pad electrodes PDE and some of the bumps BUM are not electrically connected may occur.

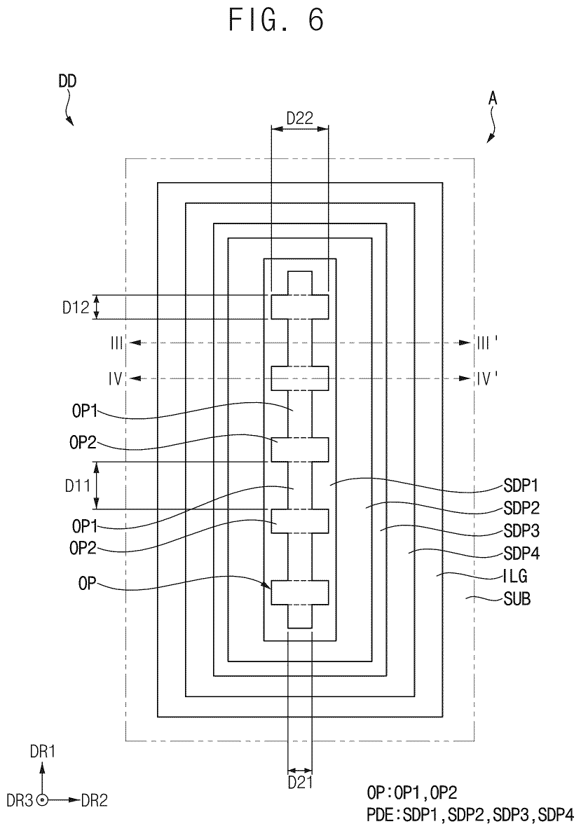

To reduce or prevent the likelihood of a contact defect of the conductive balls CB, the display device DD according to one or more embodiments of the present disclosure may include a first conductive pattern (e.g., a first conductive pattern SDP1 of FIG. 6), and an insulating layer that defines an opening (e.g., an opening OP of FIG. 6) exposing at least a portion of the first conductive pattern. In addition, the opening may have a shape that considers a diameter (or size) of each of the conductive balls CB and a planar arrangement of the conductive balls CB. A detailed description thereof will be described below with reference to FIGS. 6, 7, and 8.

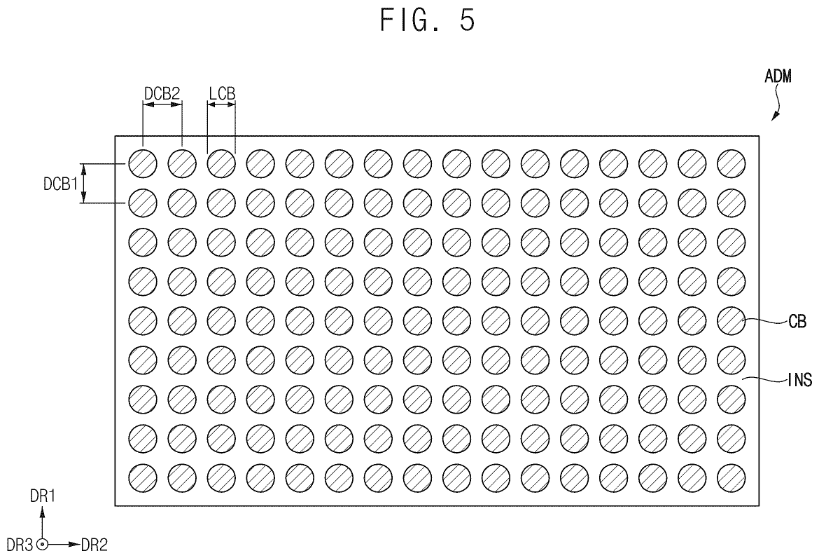

FIG. 5 is a plan view illustrating an adhesive member included in the display device of FIG. 1.

Referring to FIG. 5, the adhesive member ADM may include the adhesive material INS and the plurality of conductive balls CB.

The adhesive material INS may surround the conductive balls CB in a plan view. The adhesive material INS may be an adhesive material having insulating properties. For example, the adhesive material INS may include thermoplastic resin and/or thermoset resin.

The conductive balls CB may be repeatedly arranged along the first direction DR1 and the second direction DR2 in a plan view. For example, a diameter LCB of each of the conductive balls CB may be about 2.2 micrometers. However, the present disclosure is not limited thereto.

In one or more embodiments, the conductive balls CB may include a plurality of groups arranged in a line along the first direction DR1 in a plan view, and the plurality of groups may be arranged along the second direction DR2. For example, a first distance DCB1 in the first direction DR1 between the centers of the adjacent conductive balls CB in the first direction DR1 may be about 5.6 micrometers. In addition, a second distance DCB2 in the second direction DR2 between the centers of the conductive balls CB that are adjacent to each other in the second direction DR2 may be about 3.2 micrometers. However, the planar arrangement of the conductive balls CB and the interval between the conductive balls CB are not limited thereto. For example, the conductive balls CB may be arranged in a zigzag shape in a plan view.

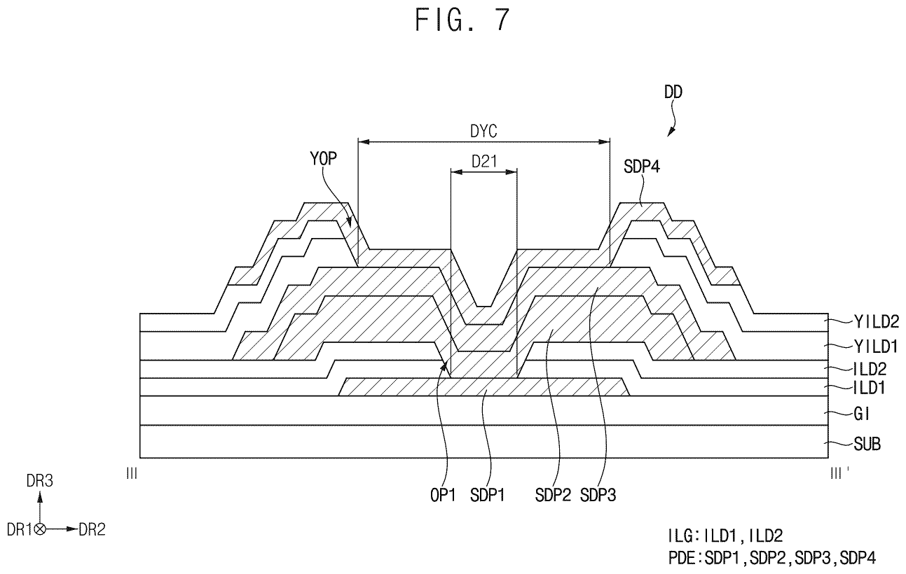

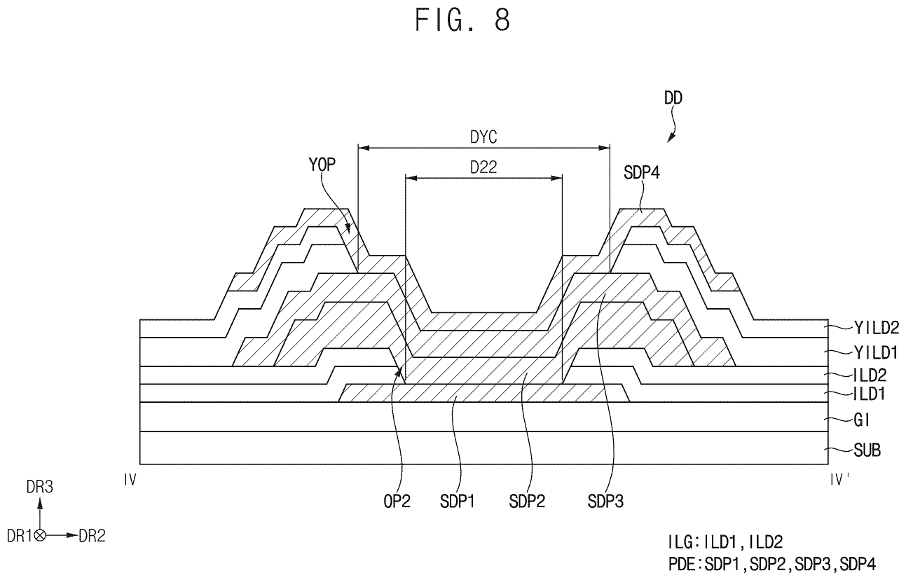

FIG. 6 is an enlarged plan view of area ‘A’ of FIG. 1. FIG. 7 is a cross-sectional view taken along the line III-III′ of FIG. 6. FIG. 8 is a cross-sectional view taken along the line IV-IV′ of FIG. 6. For example, FIG. 7 is a cross-sectional view illustrating a first opening OP1, and FIG. 8 is a cross-sectional view illustrating a second opening OP2.

Referring to FIGS. 5, 6, 7, and 8, in the pad area PDA, the display device DD according to one or more embodiments of the present disclosure may include the substrate SUB, the gate-insulating layer GI, the pad electrode PDE, an insulating layer group ILG, the first touch insulating layer YILD1, and the second touch insulating layer YILD2. The insulating layer group ILG may include the first inter-layer insulating layer ILD1 and the second inter-layer insulating layer ILD2. The pad electrode PDE may include a first conductive pattern SDP1, a second conductive pattern SDP2, a third conductive pattern SDP3, and a fourth conductive pattern SDP4.

The gate-insulating layer GI, the first inter-layer insulating layer ILD1, the second inter-layer insulating layer ILD2, the first touch insulating layer YILD1, and the second touch insulating layer YILD2, which are illustrated in FIGS. 7 and 8, may correspond to the gate-insulating layer GI, the first inter-layer insulating layer ILD1, the second inter-layer insulating layer ILD2, the first touch insulating layer YILD1, and the second touch insulating layer YILD2, which are illustrated in FIG. 2, respectively. Hereinafter, descriptions overlapping descriptions of the display device DD described with reference to FIG. 2 will be omitted or simplified.

The gate-insulating layer GI may be located on the substrate SUB, and the first conductive pattern SDP1 may be located on the gate-insulating layer GI. The first conductive pattern SDP1 may include a metal, an alloy, a metal nitride, a conductive metal oxide, a transparent conductive material, etc. These may be used alone or in combination with each other. As illustrated in FIG. 6, the first conductive pattern SDP1 may have a rectangular shape in a plan view, but the present disclosure is not limited thereto.

In one or more embodiments, the first conductive pattern SDP1 may be located on the same layer as the gate electrode GE illustrated in FIG. 2. That is, the first conductive pattern SDP1 may be formed of the same material through the same process as the gate electrode GE illustrated in FIG. 2.

The insulating layer group ILG may be located on the gate-insulating layer GI and the first conductive pattern SDP1. The insulating layer group ILG may include the first inter-layer insulating layer ILD1 and the second inter-layer insulating layer ILD2. The insulating layer group ILG may cover the first conductive pattern SDP1 on the gate-insulating layer GI, and may be located along the profile of the first conductive pattern SDP1 with a uniform thickness. The insulating layer group ILG may include an inorganic insulating material. Examples of the inorganic insulating material that may be used as the insulating layer group ILG may include silicon oxide (SiOₓ), silicon nitride (SiNₓ), silicon oxynitride (SiOₓN_{y}), etc. These may be used alone or in combination with each other.

The insulating layer group ILG may define an opening OP exposing at least a portion of the first conductive pattern SDP1. The opening OP may include a plurality of first openings OP1 and a plurality of second openings OP2.

As illustrated in FIG. 6, each of the first openings OP1 may extend in the first direction DR1, and may be spaced apart from each other in the first direction DR1. A length D11 of each of the first openings OP1 in the first direction DR1 may be greater than a width D21 of each of the first openings OP1 in the second direction DR2. Each of the first openings OP1 may have a rectangular shape in a plan view, but the present disclosure is not limited thereto.

Each of the second openings OP2 may extend in the second direction DR2, and may be spaced apart from each other in the first direction DR1. A width D12 of each of the second openings OP2 in the first direction DR1 may be less than a length D22 of each of the second openings OP2 in the second direction DR2. Each of the second openings OP2 may be located on a space where the first openings OP1 are spaced apart from each other in a plan view.

Accordingly, each of the second openings OP2 may connect the first openings OP1 adjacent to each other. Each of the second openings OP2 may have a rectangular shape in a plan view, but the present disclosure is not limited thereto.

The length D11 of each of the first openings OP1 in the first direction DR1 may be equal to the first distance DCB1 in the first direction DR1 between the centers of the conductive balls CB adjacent to each other in the first direction DR1. In other words, the length D11 of each of the first openings OP1 in the first direction DR1 may be provided by considering the planar arrangement of the conductive balls CB. For example, when the first distance DCB1 is about 5.6 micrometers, the length D11 of each of the first openings OP1 in the first direction DR1 may be about 5.2 micrometers to about 6.0 micrometers. However, the present disclosure is not limited thereto, and when the interval between the conductive balls CB varies, the length D11 of each of the first openings OP1 in the first direction DR1 may be provided differently. In one or more embodiments, the length D11 of each of the first openings OP1 in the first direction DR1 may be greater than the width D12 of each of the second openings OP2 in the first direction DR1.

The width D21 of each of the first openings OP1 in the second direction DR2 may be equal to the diameter LCB of each of the conductive balls CB. In other words, the width D21 of each of the first openings OP1 in the second direction DR2 may be provided by considering the diameter LCB of the conductive balls CB. For example, when the diameter LCB of each of the conductive balls CB is about 2.2 micrometers, the width D21 of each of the first openings OP1 in the second direction DR2 may be about 1.8 micrometers to about 2.6 micrometers. However, the present disclosure is not limited thereto, and when the diameter LCB of each of the conductive balls CB varies, the width D21 of each of the first openings OP1 in the second direction DR2 may be provided differently. In one or more embodiments, the width D21 of each of the first openings OP1 in the second direction DR2 may be less than the length D22 of each of the second openings OP2 in the second direction DR2. For example, the width D21 of each of the first openings OP1 in the second direction DR2 may be about 2.3 micrometers, and the length D22 of each of the second openings OP2 in the second direction DR2 may be about 4.2 micrometers.

In one or more embodiments, a first center of the first opening OP1 and a second center of the second opening OP2 may be positioned on an imaginary straight line extending along the first direction DR1. In other words, the first center and the second center may be positioned on the same line extending in the first direction DR1 in a plan view.

As illustrated in FIGS. 7 and 8, the second conductive pattern SDP2 may be located on the insulating layer group ILG. The second conductive pattern SDP2 may be located along the profiles of the first conductive pattern SDP1 and the insulating layer group ILG. The second conductive pattern SDP2 may contact the first conductive pattern SDP1 through the opening OP. Accordingly, the second conductive pattern SDP2 may be electrically connected to the first conductive pattern SDP1. The second conductive pattern SDP2 may have a rectangular shape in a plan view, but the present disclosure is not limited thereto.

In one or more embodiments, the second conductive pattern SDP2 may be located on the same layer as the source electrode SE and the drain electrode DE which are illustrated in FIG. 2. That is, the second conductive pattern SDP2 may be formed of the same material through the same process as the source electrode SE and drain electrode DE which are illustrated in FIG. 2.

The third conductive pattern SDP3 may be located on the insulating layer group ILG and the second conductive pattern SDP2. The third conductive pattern SDP3 may be located along the profiles of the second conductive pattern SDP2 and the insulating layer group ILG. The third conductive pattern SDP3 may contact the second conductive pattern SDP2 and cover the second conductive pattern SDP2. Accordingly, the third conductive pattern SDP3 may be electrically connected to the second conductive pattern SDP2. The third conductive pattern SDP3 may have a rectangular shape in a plan view, but the present disclosure is not limited thereto.

In one or more embodiments, the third conductive pattern SDP3 may be located on the same layer as the connection electrode LCE illustrated in FIG. 2. That is, the third conductive pattern SDP3 may be formed of the same material through the same process as the connection electrode LCE illustrated in FIG. 2. In this case, the display device DD may not include the first via-insulating layer VIA1 and the second via-insulating layer VIA2, which are illustrated in FIG. 2, in the pad area PDA.

The first touch insulating layer YILD1 and the second touch insulating layer YILD2 may be located on the insulating layer group ILG and the third conductive pattern SDP3. The first touch insulating layer YILD1 and the second touch insulating layer YILD2 may cover an edge of the third conductive pattern SDP3, and may define a touch opening YOP that exposes an upper surface of the third conductive pattern SDP3. A length DYC of the touch opening YOP in the second direction DR2 may be greater than the width D21 of each of the first openings OP1 in the second direction DR2, and may be greater than the length D22 of each of the second openings OP2 in the second direction DR2. For example, the length DYC of the touch opening YOP in the second direction DR2 may be about 7.0 micrometers.

The fourth conductive pattern SDP4 may be located on the second touch insulating layer YILD2 and the third conductive pattern SDP3. The fourth conductive pattern SDP4 may be located along the profile of the third conductive pattern SDP3 in an area that overlaps the opening OP in a plan view. The fourth conductive pattern SDP4 may contact the third conductive pattern SDP3 through the touch opening YOP. Accordingly, the fourth conductive pattern SDP4 may be electrically connected to the third conductive pattern SDP3. The fourth conductive pattern SDP4 may have a rectangular shape in a plan view, but the present disclosure is not limited thereto.

In one or more embodiments, the fourth conductive pattern SDP4 may be located on the same layer as a sensing electrode. For example, the fourth conductive pattern SDP4 may be located on the same layer as the second sensing electrode YMTL2 illustrated in FIG. 2. That is, the fourth conductive pattern SDP4 may be formed of the same material through the same process as the second sensing electrode YMTL2 illustrated in FIG. 2.

The second conductive pattern SDP2 may be located along the profiles of the insulating layer group ILG and the first conductive pattern SDP1. The third conductive pattern SDP3 may be located along the profile of the second conductive pattern SDP2. The fourth conductive pattern SDP4 may be located along the profile of the third conductive pattern SDP3 in the area that overlaps the opening OP in a plan view. Accordingly, the fourth conductive pattern SDP4 may have a concave portion that is concave toward the substrate SUB, and a width (e.g., length in the second direction DR2) of the concave portion may correspond to a length of the opening OP in the second direction DR2. That is, as illustrated in FIGS. 7 and 8, the width of the concave portion overlapping the first opening OP1 in a plan view may be relatively small, and the width of the concave portion overlapping the second opening OP2 in a plan view may be relatively large.

As described above in FIGS. 3 and 4, when the pad electrode PDE and the driving chip are bonded, one side of each of the conductive balls CB may directly contact the pad electrode PDE. For example, the conductive balls CB may directly contact the fourth conductive pattern SDP4, and the conductive balls CB may be connected to the first conductive pattern SDP1 through the third conductive pattern SDP3 and the second conductive pattern SDP2.

The display device DD according to one or more embodiments of the present disclosure may include the first conductive pattern SDP1 and the insulating layer group ILG defining the opening OP exposing at least a portion of the first conductive pattern SDP1. In addition, the opening OP may include the first openings OP1 spaced apart from each other in the first direction DR1, and the first openings OP1 may have a shape that considers the diameter LCB of each of the conductive balls CB. In other words, the width D21 of each of the first openings OP1 in the second direction DR2 may be equal to the diameter LCB of each of the conductive balls CB. In addition, the first openings OP1 may have a shape that considers the planar arrangement of the conductive balls CB. In other words, the length D11 of each of the first openings OP1 in the first direction DR1 may be equal to the distance DCB1 between the centers of the conductive balls CB adjacent to each other in the first direction DR1. Accordingly, the frequency with which the conductive balls CB are captured by the pad electrodes PDE may increase. In other words, the frequency with which the conductive balls CB directly contact the pad electrodes PDE may increase. As a result, a defect in which some of the pad electrodes PDE and some of the bumps of the driving chip are not electrically connected may be suppressed.

Similarly, the circuit board pad electrodes (e.g., the circuit board pad electrodes FPDE of FIG. 1) connected to the circuit board may have substantially the same structure as the pad electrodes PDE. That is, the insulating layer group ILG may define a circuit board opening exposing at least a portion of the circuit board pad electrodes, and the circuit board opening may have a shape that considers the diameter of each of the conductive balls CB and the planar arrangement of the conductive balls CB. Accordingly, a defect in which some of the circuit board pad electrodes and some of the bumps of the driving chip are not electrically connected may be suppressed.

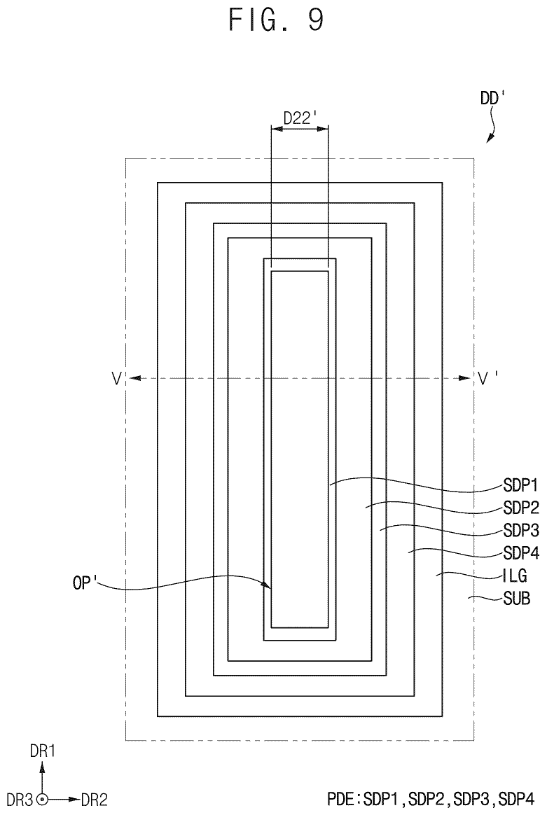

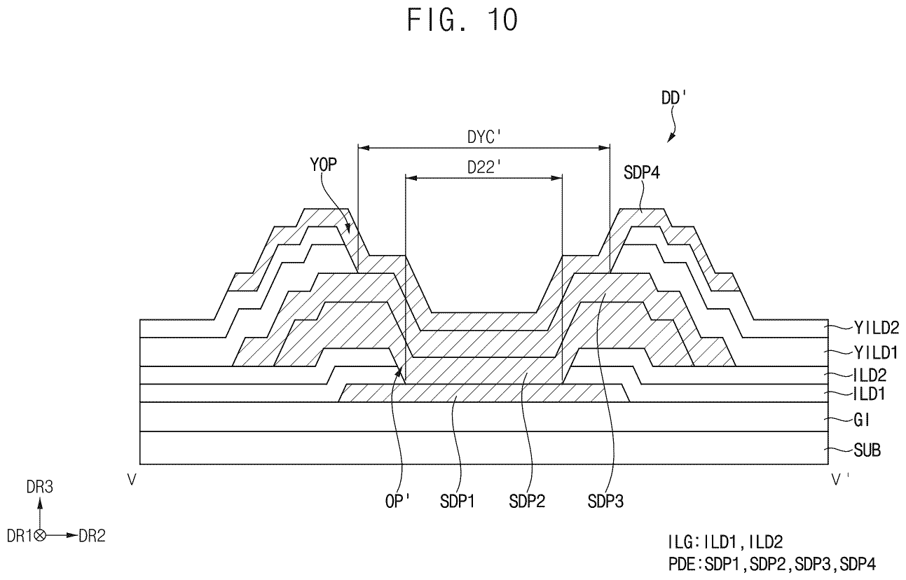

FIG. 9 is a plan view illustrating a pad area of a display device according to a comparative example. FIG. 10 is a cross-sectional view taken along the line V-V′ of FIG. 9.

Referring to FIGS. 9 and 10, a display device DD′ according to a comparative example may include a substrate SUB, a gate-insulating layer GI, pad electrodes PDE, an insulating layer group ILG, a first touch insulating layer YILD1, and a second touch insulating layer YILD2. The insulating layer group ILG may include a first inter-layer insulating layer ILD1 and a second inter-layer insulating layer ILD2. Each of the pad electrodes PDE may include a first conductive pattern SDP1, a second conductive pattern SDP2, a third conductive pattern SDP3, and a fourth conductive pattern SDP4.

The display device DD′ may be substantially the same as the display device DD described with reference to FIGS. 6 to 8, except that the insulating layer group ILG defines an opening OP′ exposing at least a portion of the first conductive pattern SDP1, and the opening OP′ has a rectangular shape in a plan view.

The opening OP′ may have a rectangular shape in a plan view. A length D22′ of the opening OP′ in the second direction DR2 may be about 4.2 micrometers.

Hereinafter, the effects of the present disclosure will be described with reference to FIGS. 6, 7, 8, 9, and 10.

The bonding resistance between the pad electrode PDE and the adhesive member (e.g., the adhesive member ADM of FIG. 5) was measured in display devices satisfying Comparative Example 1, Comparative Example 2, Example 1, and Example 2. A pressure of about 28 MPa and about 35 MPa was applied to each of the display devices satisfying the Comparative Example 1, the Comparative Example 2, the Example 1, and the Example 2 to bond the pad electrode PDE and the adhesive member, and the bonding resistance was measured. It may be interpreted that the lower the bonding resistance, the greater the frequency with which the conductive balls CB directly contact the pad electrodes PDE. In other words, it may be interpreted that the lower the bonding resistance, the greater the frequency with which the conductive balls CB are captured by the pad electrodes PDE.

The display devices (e.g., the display device DD of FIG. 6) satisfying the Example 1 and the Example 2 include the insulating layer group ILG defining the opening OP exposing at least a portion of the first conductive pattern SDP1. The opening OP includes the first openings OP1 spaced apart from each other in the first direction DR1, and the second openings OP2 connecting adjacent first openings OP1. The width D21 of each of the first openings OP1 in the second direction DR2 is about 2.2 micrometers, which is the same as the diameter LCB of each of the conductive balls CB. The length D22 of each of the second openings OP2 in the second direction DR2 is about 4.2 micrometers. The length D11 of each of the first openings OP1 in the first direction DR1 is about 5.6 micrometers, which is the same as the distance DCB1 in the first direction DR1 between the centers of the conductive balls CB adjacent to each other in the first direction DR1. In the display device satisfying the Example 1, the bonding resistance was measured immediately after bonding. In the display device satisfying the Example 2, the bonding resistance was measured about 240 hours after bonding.

The display devices (e.g., the display device DD′ of FIG. 9) satisfying the Comparative Example 1 and the Comparative Example 2 include the insulating layer group ILG defining the opening OP′ exposing at least a portion of the first conductive pattern SDP1. The opening OP′ has a rectangular shape in a plan view, and the length D22′ of the opening OP′ in the second direction DR2 is about 4.2 micrometers. In the display device satisfying the Comparative Example 1, the bonding resistance was measured immediately after bonding. In the display device satisfying the Comparative Example 2, the bonding resistance was measured about 240 hours after bonding.

As a result, referring to Table 1 below, the display device satisfying the Comparative Example 1 was measured to have the bonding resistance value of about 0.303Ω when a pressure of about 28 MPa was applied. The display device satisfying the Example 1 was measured to have the bonding resistance value of about 0.273Ω when a pressure of about 28 MPa was applied. The display device satisfying the Comparative Example 1 was measured to have the bonding resistance value of about 0.231Ω when a pressure of about 35 MPa was applied. The display device satisfying the Example 1 was measured to have the bonding resistance value of about 0.201Ω when a pressure of about 35 MPa was applied.

The display device satisfying the Comparative Example 2 was measured to have the bonding resistance value of about 0.420Ω when a pressure of about 28 MPa was applied. The display device satisfying the Example 2 was measured to have the bonding resistance value of about 0.371Ω when a pressure of about 28 MPa was applied. The display device satisfying the Comparative Example 2 was measured to have the bonding resistance value of about 0.346Ω when a pressure of about 35 MPa was applied. The display device satisfying the Example 2 was measured to have the bonding resistance value of about 0.286Ω when a pressure of about 35 MPa was applied.

TABLE 1

| | Pressure | Bonding resistance |
|---|---|---|
| | (MPa) | value (Ω) |
| Comparative Example 1 | 28 | 0.303 |
| (immediately after | | |
| bonding) | 35 | 0.231 |
| Example 1 | 28 | 0.273 |
| (immediately after | | |
| bonding) | 35 | 0.201 |
| Comparative Example 2 | 28 | 0.420 |
| (240 hours after | 35 | 0.346 |
| bonding) | | |
| Example 2 | 28 | 0.371 |
| (240 hours after | 35 | 0.286 |
| bonding) | | |

From these results, it can be seen that the display device DD according to one or more embodiments of the present disclosure includes an insulating layer defining the first openings OP1, while taking into account the diameter LCB of each of the conductive balls CB and the planar arrangement of the conductive balls CB, thereby reducing the bonding resistance between the pad electrode PDE and the adhesive member. In other words, it can be seen that the display device DD increases the frequency of direct contact between the conductive balls CB and the pad electrode PDE.

The present disclosure may be applied to various display devices. For example, the present disclosure is applicable to various display devices, such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims, with functional equivalents thereof to be included therein.

What is claimed is:

1. A display device comprising:
a substrate comprising a display area, and a pad area at one side of the display area;
a pad electrode above the substrate in the pad area, and comprising a first conductive pattern;
a driving chip above the substrate in the pad area, and overlapping the pad electrode in plan view;
an insulating layer above the substrate, and defining an opening exposing a portion of the first conductive pattern; and
an adhesive member connecting the pad electrode and the driving chip, and comprising conductive balls repeatedly arranged along a first direction,
wherein the opening comprises:
first openings spaced apart from each other in the first direction, and having a first width in a second direction crossing the first direction that is substantially equal to a diameter of the conductive balls; and
second openings respectively connecting adjacent ones of the first openings.

2. The display device of claim 1, wherein a distance in the first direction between centers of adjacent ones of the conductive balls in the first direction is substantially equal to a first length of the first openings in the first direction.

3. The display device of claim 1, wherein a first length of the first openings in the first direction is greater than a second width of the second openings in the first direction.

4. The display device of claim 1, wherein the first width is less than a second length of the second openings in the second direction.

5. The display device of claim 1, wherein a first length of the first openings in the first direction is greater than the first width, and
wherein a second width of the second openings in the first direction is less than a second length of the second openings in the second direction.

6. The display device of claim 1, wherein the second openings are alternately arranged with the first openings in plan view.

7. The display device of claim 1, wherein the first openings and the second openings are aligned along the first direction.

8. The display device of claim 1, further comprising:
an active pattern above the substrate in the display area;
a gate electrode above the active pattern; and
a source electrode and a drain electrode at a layer above the gate electrode,
wherein the first conductive pattern is at a same layer as the gate electrode.

9. The display device of claim 8, further comprising:
a connection electrode above the drain electrode in the display area; and
a sensing electrode above the connection electrode.

10. The display device of claim 9, wherein the pad electrode further comprises:
a second conductive pattern above the first conductive pattern, and at a same layer as the source electrode and the drain electrode;
a third conductive pattern above the second conductive pattern, and at a same layer as the connection electrode; and
a fourth conductive pattern above the third conductive pattern, and at a same layer as the sensing electrode.

11. The display device of claim 10, wherein the second conductive pattern is located along profiles of the first conductive pattern and the insulating layer.

12. The display device of claim 11, wherein the third conductive pattern covers the second conductive pattern, and is located along profiles of the second conductive pattern and the insulating layer.

13. The display device of claim 12, wherein the fourth conductive pattern is located along a profile of the third conductive pattern and overlapping the opening in plan view.

14. A display device comprising:
a substrate comprising a display area, and a pad area at one side of the display area;
a pad electrode above the substrate in the pad area, and comprising a first conductive pattern;
a driving chip above the substrate in the pad area, and overlapping the pad electrode in plan view;
an insulating layer above the substrate, and defining an opening exposing a portion of the first conductive pattern; and
an adhesive member connecting the pad electrode and the driving chip, and comprising conductive balls repeatedly arranged along a first direction,
wherein the opening comprises:
first openings spaced apart from each other in the first direction, having a first length in the first direction substantially equal to a distance between centers of adjacent ones of the conductive balls in the first direction; and
second openings respectively connecting adjacent ones of the first openings.

15. The display device of claim 14, wherein the first length is greater than a second width of the second openings in the first direction.

16. The display device of claim 14, wherein a first width of the first openings in a second direction crossing the first direction is less than a second length of the second openings in the second direction.

17. The display device of claim 14, wherein the first length is greater than a first width of the first openings in a second direction crossing the first direction, and
wherein a second width of the second openings in the first direction is less than a second length of the second openings in the second direction.

18. The display device of claim 14, wherein the first openings and the second openings are aligned along the first direction.

19. The display device of claim 14, further comprising:
an active pattern above the substrate in the display area;
a gate electrode above the active pattern;
a source electrode and a drain electrode at a layer above the gate electrode;
a connection electrode above the drain electrode; and
a sensing electrode above the connection electrode,
wherein the first conductive pattern is at a same layer as the gate electrode.

20. The display device of claim 19, wherein the pad electrode further comprises:
a second conductive pattern above the first conductive pattern at a same layer as the source electrode and the drain electrode;
a third conductive pattern above the second conductive pattern at a same layer as the connection electrode; and
a fourth conductive pattern above the third conductive pattern at a same layer as the sensing electrode.
